(19) United States
(12) Patent Application Publication
(10) Pub. No.: US 2018/0024169 A1
(43) Pub. Date: Jan. 25, 2018

(54) FULL WAVE RECTIFIED ISOLATED CURRENT SENSOR

(71) Applicant: IntelliPower, Inc., Orange, CA (US)

(72) Inventor: Norman C. Walker, Solana Beach, CA (US)

(21) Appl. No.: 15/215,358

(22) Filed: Jul. 20, 2016

(51) Int. Cl. G01R 15/18; H01F 27/28

(52) U.S. Cl. CPC G01R 15/183; H01F 27/2823; H01F 27/2895

(57) ABSTRACT

A small wire is wound several times around a powdered metal toroidal core to sense voltage produce by single polarity current flowing through a larger wire passing through the toroid. An integrator circuit integrates the voltage in the small wire to produce an output voltage as a measure of AC and DC components of the single polarity current, such as a full wave rectified current.

### FIELD

Present principles generally apply to full wave rectified isolated current sensors.

### BACKGROUND

In applications such as power factor correction, it is often required to sense full wave rectified current. Typically, there are both DC and AC components in such a waveform and it is often desirable to sense both.

As understood herein, adding a resistor in series with one of the current leads as a sensor consumes a relatively large amount power and does not have an electrically isolated output, which is sometimes desirable, depending on the application. Hall effect sensors may be used if sensing both DC and AC components of a full wave rectified current is desirable with a sensor having an isolated output, but Hall effect sensors, as understood herein, are relatively expensive, and those capable of sensing higher currents typically have relatively slow response times. Yet again, so-called Rogowski coils have been used to sense current but such devices sense only the AC component of the current. Similarly, a current transformer cannot be used to sense both AC and DC components of a waveform because the DC component of the current will cause the transformer to saturate.

### SUMMARY

Present principles recognize that a larger induced voltage, induced by current flowing through a single wire passing through a magnetic core, can be realized using a powdered metal (such as powdered Iron) toroidal core and winding a smaller pick up wire around it, and then sending the induced voltage to an integrator which is biased so that its output goes to zero at the cusps of the current. This takes advantage of the fact that the full wave rectified waveform is zero each time the AC line voltage passes through zero.

Accordingly, a circuit includes a first wire wound plural times on a magnetic core, preferably a powdered metal toroid core (PMTC), and a single second wire for carrying i(t), which is current to be sensed. The single second wire extends through a central opening formed by the PMTC. Locations at which an output voltage v(t) representing derivative of the current to be sensed i(t) are on the first wire, and an integrator is connected to the locations and is configured to integrate the output voltage v(t) to produce an indication of AC and DC components of the current to be sensed i(t).

In examples, the second wire has a larger diameter than the first wire. In some implementations the size and permeability of the PMTC are established so that the PMTC will not be saturated by a maximum expected current to be sensed i(t). In non-limiting examples the output voltage v(t) is present on at least part of the first wire when the second wire carries the current to be sensed and, is given by the equation v(t)=−N(AL)di(t)/dt wherein N=number of turns of the first wire around the PMTC, and AL=inductance of a single turn of first wire on the PMTC.

In example embodiments the integrator includes an integrator circuit portion integrating the output voltage v(t). An example integrator circuit portion may include a first resistor R1 in series with a first one of the locations on the first wires, and an operational amplifier (opamp) U1 having an inverted input connected to the first resistor R1 and a non-inverting input connected to a second one of the locations. The opamp U1 has a voltage output. A capacitor can be electrically connected between the inverting input and the output of the opamp U1 in parallel with the opamp U1. Voltage at the voltage output of the opamp U1 represents an integrated value of DC and AC components in the input current i(t).

In example implementations, the integrator circuit portion may further include a second resistor R2 connected between the inverting input of the opamp U1 and the capacitor. A voltage offset source can be connected to the second resistor R2, such as between the second resistor R2 and ground.

In the example circuit described above, voltage the voltage output of opamp U1=N(AL)R₁C, wherein R₁ is the resistance of the first resistor R1, and C is the capacitance of the capacitor. Furthermore, if desired the circuit may be arranged and configured such that VbR₁/(R₁+R₂)>Vos, wherein Vb is the voltage of the voltage offset source, R₁ is the resistance of the first resistor R1, R₂ is the resistance of the second resistor R2, and Vos is a voltage offset of the opamp U1.

In another aspect, a device for reproducing the waveform of a current having a DC component and an AC component periodically going to zero includes a coil assembly with an open circuit secondary, and an integrator connected to the open circuit secondary for receiving input from the secondary. The integrator produces an output representative of the input and is biased such that the output is zero when the AC component of the output is zero.

In another aspect, a method includes receiving, from a second wire wound around a core forming an aperture, an output voltage v(t) representing the derivative of full wave rectified current to be sensed i(t) on first wire extending through the aperture. The method also includes integrating the output voltage v(t) to produce an indication of DC and AC components of the current to be sensed i(t).

The details of the present application, both as to its structure and operation, can best be understood in reference to the accompanying drawings, in which like reference numerals refer to like parts, and in which:

### BRIEF DESCRIPTION OF TUE DRAWINGS

FIG. 1 illustrates a waveform of a full wave rectified current i(t) to be sensed;

FIG. 2 is a diagram of a larger wire carrying the current i(t) and passing through the aperture or annulus of a toroidal shaped powdered metal core around which is wound a smaller wire, with a voltage v(t) induced by the current i(t) being taken off terminals (such as the ends) of the smaller wire⁻.

FIG. 3 is a schematic diagram of another type of toroidal core; and

FIG. 4 is a diagram of a circuit receiving the induced voltage v(t) and integrating it to produce an output voltage vo(t) that is a measure of the AC and DC components of the current i(t) to be sensed.

### DETAILED DESCRIPTION

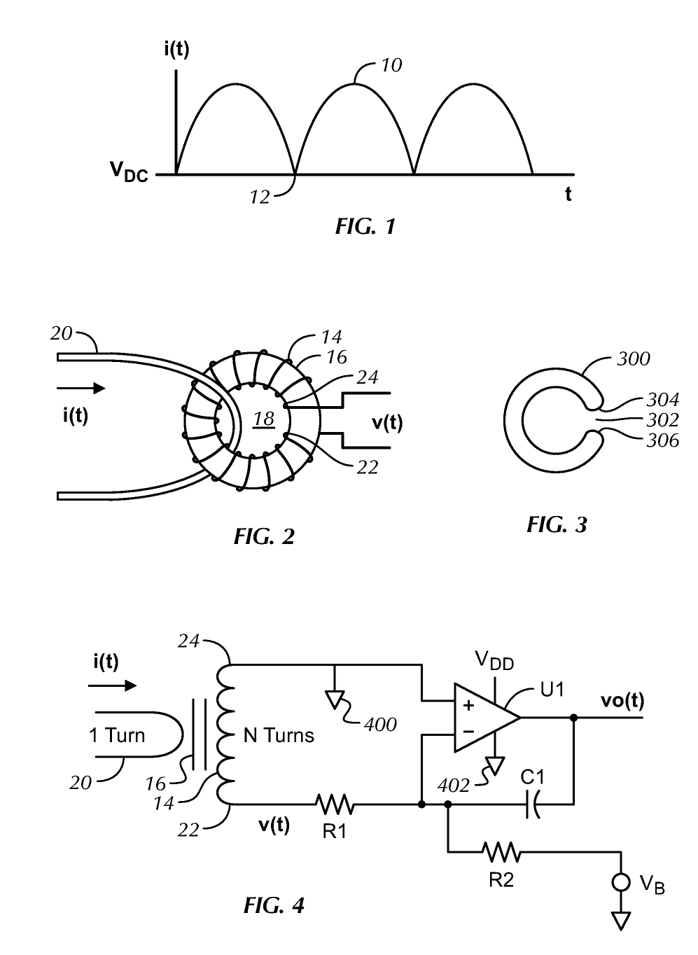

FIG. 1 shows the sinusoidal waveform 10 of a full wave rectified (FWR) current i(t) to be sensed, with amplitude on the y-axis as a function of time on the x-axis. Being rectified alternating current (AC), the waveform 10 has cusps 12 between adjacent half-cycles. The cusps 12 are at the zero point of the current i(t).

FIG. 2 shows that a first wire 14 is wound plural (N) times on a toroidal core 16. In an example, the toroidal core 16 is made of powdered metal such as powdered Iron, and the core 16 may be solid except for the toroidal aperture or opening 18 it forms. Thus, the first wire 14 is wound N times around the toroidal body of the core 16 and may be wound tightly around the body of the core 16 without any air gap between the first wire 14 and core 16.

A second wire 20, which in some embodiments is established by one and only one single wire, can be positioned through the toroidal aperture or opening 18 formed by the core 16. Typically, the second wire 20 may not touch the body of the core 16. The second wire 20 may have a larger diameter than the first wire 14. In any case, the current to be sensed i(t), an example of which is shown in FIG. 1, is carried through the second wire 20.

As shown in FIG. 2, one or more locations 22, 24 at which an output voltage v(t) representing the derivative of the current to be sensed i(t) can be on the first wire 14. The locations 22, 24 may be the ends of the first wire 14 or some other portion of the wire and may include electrical terminal structure. As set forth further below, an integrator is connected to the locations 22, 24 to integrate the output voltage v(t) to produce an indication of AC and DC components of the current to be sensed i(t). Thus, the output voltage v(t) is induced by the input current to be sensed i(t).

The output voltage v(t) of the coil can be given by:
v(t)=−N ALdi(t)/dt, wherein N=number of turns of the first wire 14 around the core 16 and AL=inductance of a single turn of the first wire 14 on the core 16.

Note that while the core 16 shown in FIG. 2 has a perfect toroid shape and hence is endless, FIG. 3 shows that an alternate toroidal core may have a toroidal body 300 in which is termed a gap 302 between two ends 304, 306. As contemplated herein, a core of any shape can be used, including an air core, recognizing, however, that because the scale factor depends on the inductance, the core should not saturate due to the current to be measured. An air core will not saturate but the inductance is very low. So for that reason a powdered metal (e.g., iron) core is preferred. Other shapes can work, but the scale factor would be less predictable. In any case, the size and permeability of the core should be established so that the core will not be saturated by the maximum expected current.

Turning now to FIG. 4, the first and second wires 14, 20 and core 16 are illustrated in electric schematic along with an example of the above-described integrator, which includes an integrator circuit that receives the output voltage v(t) from the first wire 14. As shown, a first electrical path from the first location 22 at which the output voltage is taken leads to a first resistor R1, which is in series with the first location 22. As also shown, an operational amplifier (opamp) U1 has an inverted input (denoted by the negative sign in FIG. 4) connected to the first resistor R1 and a non-inverting input (denoted by the positive sign in FIG. 4) connected to the second location 24, with the electrical path between the second location 24 and opamp U1 being grounded if desired as indicated at 400. As further indicated in FIG. 4, the opamp U1 produces a voltage output Vo(t). The opamp U1 may have a power supply voltage V_{DD} input to it and may also he grounded at a location represented at 402.

A capacitor C1 may be electrically connected as shown between the inverting input of the opamp U1 and the output of the opamp U1, in parallel with the opamp U1. A second resistor R2 may be connected between the inverting input of the opamp U1 and the capacitor C1. A voltage offset source V_{B} can he connected downstream of the second resistor R2, e.g., the voltage offset source can be connected in series between the second resistor and ground.

With the above circuit in mind, the opamp output voltage Vo(t)=N(AL)R₁Ci(t), wherein R₁ is the resistance of the first resistor R1 and C is the capacitance of the capacitor, with N and AL assuming the values described previously. This voltage at the voltage output of the opamp U1 represents an integrated value of DC and AC components in the input current i(t).

In a preferred embodiment, the following constraint is satisfied:

V_{b}R₁/(R₁+R₂)>Vos, wherein V_{b} is the voltage of the voltage offset source V_{B}, R₁ is the resistance of the first resistor R1, R₂ is the resistance of the second resistor R2, and Vos is the voltage offset of the opamp U1.

Thus, the opamp U1 may have a rail to rail input with very low voltage offset, Vos.

Note that vo(t) is a comparatively accurate representation of i(t) with a scale factor of NAL/R₁C₁ except that vo(t) may slowly drift up or down due to Vos, the voltage offset of U1. If it drifts down, it will stop when the negative cusps of vo(t) reach the negative rail of U1. As recognized herein, because Vos is very small, there will be negligible error in such a case. However, if vo(t) drifts up, there a large DC error in vo(t) may be introduced absent the positive DC offset that is added to the input of U1 by V_{B} and R2 to ensure vo(t) drifts down. Meeting the above constraint facilitates this error prevention.

In lieu of using the voltage offset source V_{B} and the second resistor R2, a negative voltage may be input to the non-inverted (+) input of the opamp U1. Yet again, integrated circuits (ICs) may be configured with the correct right polarity of offset, or the integrator may be made from discrete components and the bias discussed above provided for in the circuit.

While the particular FULL WAVE RECTIFIED ISOLATED CURRENT SENSOR is herein shown and described in detail, it is to be understood that the subject matter which is encompassed by the present invention is limited only by the claims.

Components included in one embodiment can be used in other embodiments in any appropriate combination. For example, any of the various components described herein and/or depicted in the Figures may be combined, interchanged or excluded from other embodiments.

“A system having at least one of A, B, and C” (likewise “a system having at least one of A, B, or C” and “a system having at least one of A, B, C”) includes systems that have A alone, B alone, C alone, A and B together, A and C together, B and C together, and/or A, B, and C together, etc.

What is claimed is:

1. A circuit comprising:
at least one first wire wound plural times on a magnetic core;
a single second wire for carrying i(t), wherein i(t) is a current to be sensed, the single second wire extending through an opening formed by the magnetic core;
locations at which an output voltage v(t) representing the current to be sensed i(t) on the first wire; and
an integrator connected to the locations and configured to integrate the output voltage v(t) to produce an indication of AC and DC components of the current to be sensed i(t).

2. The circuit of claim 1, wherein the second wire has a larger diameter than the first wire.

3. The circuit of claim 1, wherein the magnetic core is a powdered metal toroidal core (PMTC).

4. The circuit of claim 3, wherein a size and permeability of the PMTC are established so that the PMTC will not be saturated by a maximum expected current to be sensed i(t).

5. The circuit of claim 1, wherein the output voltage v(t) is present on at least part of the first wire when the second wire carries the current to be sensed, the output voltage v(t) being:
v(t)=−N(AL)di(t)/dt, wherein
N=number of turns of the first wire around the toroidal core, and AL=inductance of a single turn of first wire on the toroidal core.

6. The circuit of claim 1, wherein the integrator comprises an integrator circuit portion integrating the output voltage v(t).

7. The circuit of claim 6, wherein the integrator circuit portion comprises:
a first resistor R1 in series with a first one of the locations of the first wire;
an operational amplifier (opamp) U1 having an inverted input connected to the first resistor R1 and a non-inverting input connected to a second one of the locations, the opamp U1 having a voltage output; and
a capacitor electrically connected between the inverting input and the output of the opamp U1 in parallel with the opamp U1, voltage at the voltage output of the opamp U1 representing an integrated value of DC and AC components in the input current i(t).

8. the circuit of claim 7, wherein the integrator circuit portion further comprises:
a second resistor R2 connected between the inverting input of the opamp U1 and the capacitor and a voltage offset source connected to the second resistor R2.

8. the circuit of claim 8, wherein the voltage offset source is connected between the second resistor R2 and ground.

10. The circuit of claim 7, wherein:
voltage at voltage output of opamp U1=N(AL)R₁C, wherein R1 is the resistance of the first resistor R1 and C is the capacitance of the capacitor.

11. The circuit of claim 8, wherein:
VbR₁/(R₁+R₂)>Vos, wherein Vb is the voltage of the voltage offset source, R₁ is the resistance of the first resistor R1, R₂ is the resistance of the second resistor R2, and Vos is a voltage offset of the opamp U1.

12. A device for reproducing the waveform of a current having a DC component and an AC component periodically going to zero, comprising:
a coil assembly with an open circuit secondary; and
an integrator connected to the open circuit secondary for receiving input from the secondary, the integrator having an output representative of the input and being biased such that the output is zero when an AC component of the input is zero.

13. The device of claim 12, wherein the coil assembly comprises:
at least one first wire wound plural times on a powdered metal toroid core (PMTC);
a single second wire for carrying i(t), wherein i(t) is current to be sensed, the single second wire extending through a central opening formed by the PMTC; and
terminals at which an output voltage v(t) representing the current to be sensed i(t) on the first wire.

14. The device of claim 13, wherein the integrator comprises an integrator circuit portion integrating the output voltage v(t).

15. The device of claim 14, wherein the integrator circuit portion comprises:
a first resistor R1 in series with a first one of the locations;
an operational amplifier (opamp) U1 having an inverted input connected to the first resistor R1 and a non-inverting input connected to a second one of the locations, the opamp U1 having a voltage output; and
a capacitor electrically connected between the inverting input and the output of the opamp U1 in parallel with the opamp U1, voltage at the voltage output of the opamp U1 representing an integrated value of DC and AC components in the input current i(t).

16. device of claim 15, wherein the integrator circuit portion further comprises:
a second resistor R2 connected between the inverting input of the opamp U1 and the capacitor and a voltage offset source connected to the second resistor R2.

17. The device of claim 16, wherein the voltage offset source is connected between the second resistor R2 and ground.

18. The device of claim 15, wherein:
voltage at voltage output of opamp U1=N(AL)R₁Ci(t), wherein R₁ is the resistance of the first resistor R1 and C is the capacitance of the capacitor.

19. device of claim 16, wherein:
VbR₁/(R₁−R₂)>Vos, wherein Vb is the voltage of the voltage offset source, R₁ is the resistance of the first resistor R1, R₂ is the resistance of the second resistor R2, and Vos is a voltage offset of the opamp U1.

20. A method, comprising:
receiving, from a second wire wound around a core forming an aperture, an output voltage v(t) representing full wave rectified current to be sensed i(t) on first wire extending through the aperture; and
integrating the output voltage v(t) to produce an indication of DC and AC components of the current to be sensed i(t).
